(19) United States
(12) Patent Application Publication
(10) Pub. No.: US 2026/0363117 A1
(43) Pub. Date: Nov. 12, 2026

(54) PACKAGE MODULE AND METHOD OF MANUFACTURING THE SAME

(71) Applicant: USI Science and Technology (Shenzhen) Co., Ltd., Shenzhen (CN)

(72) Inventor: Chih-Yu CHEN, Shenzhen (CN)

(21) Appl. No.: 19/668,559

(22) Filed: May 5, 2026

(30) Foreign Application Priority Data
May 7, 2025 (CN) 202510582926.4

(51) Int. Cl. H10W 70/654; H10W 70/00; H10W 70/685; H10W 74/01; H10W 74/10

(52) U.S. Cl. CPC H10W 70/654; H10W 70/099; H10W 70/685; H10W 74/01; H10W 74/121

(57) ABSTRACT

same. The package module comprises: a substrate, wherein one side surface of the substrate is provided with a metal conductive layer; a first terminal, wherein the first terminal is a three-dimensional terminal, the first terminal comprises a first surface, a second surface and a side surface, and the first surface is electrically connected to the metal conductive layer; a first encapsulating member, encapsulating one side surface of the substrate and the side surface of the first terminal, the first encapsulating member is provided with a recess corresponding to the first terminal, and the recess is configured to expose the second surface; a second terminal, wherein the second terminal comprising a first end, and the first end being electrically connected to the second surface of the first terminal; and a second encapsulating member, encapsulating the second surface of the first terminal, the first end of the second terminal, and at least a portion of the second terminal. The package module of the present disclosure, increases the electrical clearance and creepage distance between terminals of the package module via the second encapsulating member, thereby achieving protection equivalent to a package module without upper surface connection terminals, and improving the reliability of the package module.

### TECHNICAL FIELD

The present disclosure mainly relates to the field of semiconductor technology, and specifically relates to a package module and method of manufacturing the same.

### BACKGROUND

In conventional package modules, a substrate is electrically connected to a plurality of power terminals and signal terminals, both of which are led out from the periphery of the package module. Adequate spacing must be provided between these terminals to satisfy the requirements for electrical clearance and creepage distance. By arranging power terminals and signal terminals perpendicularly on the upper surface of the package module, the electrical clearance and creepage distance can be effectively increased, thereby enabling an optimized pinout for semiconductor devices.

However, arranging power terminals and signal terminals on the upper surface of the package module increases the difficulty of module design. The package module requires reserved holes for the power terminals and signal terminals, and these holes are liable to be blocked due to glue overflow during molding. Once blocked, the electrical connection between the terminals and the substrate cannot be properly established, thereby reducing the yield rate of the package module. In addition, the power terminals and signal terminals arranged on the upper surface of the package module are susceptible to various types of corrosion owing to their exposed metal bonding surfaces, resulting in low reliability.

Therefore, there is an urgent need for a novel package module that can increase the electrical clearance and creepage distance between terminals of the package module, achieving protection equivalent to a package module without upper surface connection terminals, and improving the reliability of the package module.

### SUMMARY

To solve the above technical problem, the present disclosure provides a package module and method of manufacturing the same, which can increase the electrical clearance and creepage distance between terminals of the package module, achieving protection equivalent to a package module without upper surface connection terminals, and improving the reliability of the package module.

To solve the above technical problem, the present disclosure provides a package module, comprising: a substrate, wherein one side surface of the substrate is provided with a metal conductive layer; a first terminal, wherein the first terminal is a three-dimensional terminal, the first terminal comprises a first surface, a second surface and a side surface, and the first surface is electrically connected to the metal conductive layer; a first encapsulating member, encapsulating one side surface of the substrate and the side surface of the first terminal, the first encapsulating member is provided with a recess corresponding to the first terminal, and the recess is configured to expose the second surface; a second terminal, wherein the second terminal comprising a first end, and the first end being electrically connected to the second surface of the first terminal; and a second encapsulating member, encapsulating the second surface of the first terminal, the first end of the second terminal, and at least a portion of the second terminal.

In some embodiments, the depth of the recess is greater than or equal to 0.5 millimeters.

In some embodiments, the package module further comprising: a sleeve, wherein the sleeve is fitted over the second terminal and forms an annular space with the second terminal; a bottom of the sleeve extends to the recess, the second encapsulating member completely fills the annular space and encapsulates a portion of a circumferential surface of the second terminal.

In some embodiments, the depth of the recess is greater than or equal to 1 millimeter.

In some embodiments, the first end of the second terminal is a flange.

In some embodiments, the second encapsulating member comprises a protrusion, the protrusion surrounds a circumferential surface of the second terminal, and the protrusion is conical or dome-shaped.

In some embodiments, the manner of electrically connecting the first surface to the metal conductive layer comprises any one or a combination of more of sintering, brazing and ultrasonic welding.

In some embodiments, the manner of electrically connecting the first end to the second surface of the first terminal comprises any one or a combination of more of sintering, brazing and laser welding.

To solve the above technical problem, the present disclosure further provides a method of manufacturing a package module, which is configured to manufacture the package module as described above. The method of manufacturing the package module comprises: electrically connecting the first surface of the first terminal to the metal conductive layer; molding one side surface of the substrate and the side surface of the first terminal to form the first encapsulating member, the first encapsulating member is provided with a recess corresponding to the first terminal, and the recess is configured to expose the second surface; electrically connecting the first end of the second terminal to the second surface of the first terminal; and potting to form the second encapsulating member, the second encapsulating member encapsulates the second surface of the first terminal, the first end of the second terminal, and at least a portion of the second terminal.

In some embodiments, the method of manufacturing a package module further comprises: fitting a sleeve over the second terminal to form an annular space between the sleeve and the second terminal, and extending a bottom of the sleeve to the recess, wherein the second encapsulating member further completely fills the annular space and encapsulates a portion of a circumferential surface of the second terminal.

In the package module of the present disclosure, the first encapsulating member encapsulates one side surface of the substrate and the side surface of the first terminal, and the second encapsulating member encapsulates the second surface of the first terminal, the first end of the second terminal, and at least a portion of the second terminal. Such arrangement can effectively protect the first terminal and the second terminal against corrosion, achieving protection equivalent to a package module without upper surface connection terminals, and improving the reliability of the package module. The second encapsulating member can also increase the electrical clearance and creepage distance between the terminals of the package module.

Therefore, the package module of the present disclosure allows terminals with electrical properties to extend from its upper surface, and increases the electrical clearance and creepage distance between terminals of the package module via the second encapsulating member, thereby achieving protection capability equivalent to that of the package module without upper surface connection terminals, and improving the reliability of the package module 100.

### BRIEF DESCRIPTION OF THE DRAWINGS

The accompanying drawings are included to provide a further understanding of the present disclosure, and are incorporated in and constitute a part of the present disclosure. The drawings illustrate embodiments of the present disclosure, and together with the description, serve to explain the principles of the present disclosure. In the drawings:

FIG. 1 is a schematic perspective diagram of a package module provided by an embodiment of the present disclosure;

FIG. 2 is a schematic diagram of a package module provided by an embodiment of the present disclosure after the first encapsulating member is removed;

FIG. 3 is a schematic diagram of a package module comprising a substrate and the first terminal provided by an embodiment of the present disclosure;

FIG. 4 is a schematic diagram of a package module comprising the substrate, the first terminal and the first encapsulating member according to an embodiment of the present disclosure;

FIG. 5 is a schematic diagram of another package module after removing the first encapsulating member according to an embodiment of the present disclosure;

FIG. 6 is a schematic diagram of a package module after removing the second encapsulating member according to an embodiment of the present disclosure;

FIG. 7 is a schematic diagram of another package module provided by an embodiment of the present disclosure;

FIG. 8 is a schematic diagram of a package module of FIG. 7 after removing the first encapsulating member;

FIG. 9 is a schematic diagram of the connection of a first terminal, a second terminal, a second encapsulating member and a sleeve;

FIG. 10 is a schematic diagram of a method of manufacturing a package module provided by an embodiment of the present disclosure.

### REFERENCE NUMERALS

package module, 100;
substrate, 110;
metal conductive layer, 111;
bonding wire, 112;
substrate circuit, 113;
electronic component, 114;
one side surface of the substrate, 115;
first terminal, 120;
first surface, 121;
side surface, 122;
second surface, 123;
second terminal, 130;
first end, 131;
flange, 132;
connecting terminal, 133;
shaft, 134;
first encapsulating member, 140;
second encapsulating member, 150;
recess, 160;
sleeve, 170;
protrusion, 171;
annular space, 172;
first direction, x;
second direction, y.

### PREFERRED EMBODIMENT OF THE PRESENT DISCLOSURE

To more clearly illustrate the technical solutions of the embodiments of the present disclosure, a brief introduction to the accompanying drawings used in the description of the embodiments is provided below. Obviously, the drawings depicted below are merely some examples or embodiments of the present disclosure. For those of ordinary skill in the art, without creative efforts, the present disclosure may be applied to other similar scenarios based on these drawings. Unless obvious from the context or otherwise stated, the same reference numerals in the figures represent the same structures or operations.

As shown in the present disclosure, unless the context clearly indicates an exception, words such as “a”, “an”, “one” and/or “the” are not intended to refer to a singular form, but may include a plural form. Generally speaking, the terms “comprising” and “including” only indicate that the clearly identified steps and elements are included, and these steps and elements do not constitute an exclusive list. A method or device may also include other steps or elements.

Unless specifically stated otherwise, the relative arrangements of components and steps, numerical expressions, and numerical values set forth in these embodiments do not limit the scope of the present disclosure. Meanwhile, it should be understood that, for convenience of description, the dimensions of various parts shown in the drawings are not drawn in accordance with actual proportional relationships. Technologies, methods, and equipment known to one of ordinary skill in the art may not be discussed in detail, but where appropriate, such technologies, methods, and equipment shall be regarded as part of the specification. In all examples shown and discussed herein, any specific value shall be construed as merely illustrative rather than limiting. Therefore, other examples of the exemplary embodiments may have different values. It should be noted that similar reference numerals and letters denote similar items in the following drawings, and therefore, once an item is defined in one drawing, no further discussion is required in subsequent drawings.

In the description of the present disclosure, it should be understood that the orientation words such as “front, rear, upper, lower, left, right”, “lateral, vertical, perpendicular, horizontal” and “top, bottom” are generally based on the orientation or positional relationships shown in the accompanying drawings. These terms are used only for the convenience of describing the present disclosure and simplifying the description. Unless indicated to the contrary, such orientation terms do not indicate or imply that the device or element referred to must have a specific orientation or be constructed and operated in a specific orientation, and therefore shall not be construed as limiting the scope of protection of the present disclosure. The orientation terms “inner” and “outer” refer to the interior and exterior relative to the contour of each component itself.

For the convenience of description, spatially relative terms such as “on . . . ”, “above . . . ”, “on the upper surface of . . . ”, “upper” may be used herein to describe the spatial positional relationship between one device or feature and other devices or features as shown in the drawings. It should be understood that the spatially relative terms are intended to include different orientations of the device in use or operation other than the orientation described in the drawings. For example, if the device in the drawings is inverted, the device described as “above other devices or structures” or “on other devices or structures” will then be positioned as “below other devices or structures” or “under other devices or structures”. Thus, the exemplary term “above . . . ” may include both orientations of “above” and “below”. The device may also be positioned in other different ways (rotated 90 degrees or in other orientations), and the spatial relative descriptions herein should be interpreted accordingly.

In addition, it should be noted that the use of words such as “first” and “second” to define components is only for the convenience of distinguishing corresponding components. Unless otherwise stated, the above words have no special meaning and thus cannot be understood as a limitation on the protection scope of the present disclosure. In addition, although the terms used in the present disclosure are selected from well-known and commonly used terms, some terms in the description of the present disclosure may be selected by the applicant according to his or her judgment, and their detailed meanings are explained in the relevant part of the description herein. Furthermore, the present disclosure requires not only to be understood through the actually used terms, but also through the meaning implied by each term.

Flowcharts are used in the present disclosure to illustrate the operations performed by systems according to the embodiments of the present disclosure. It should be understood that the preceding or following operations are not necessarily performed in an exact order. On the contrary, the various steps can be processed in reverse order or simultaneously. At the same time, other operations can be added to these processes, or a step or several steps can be removed from these processes.

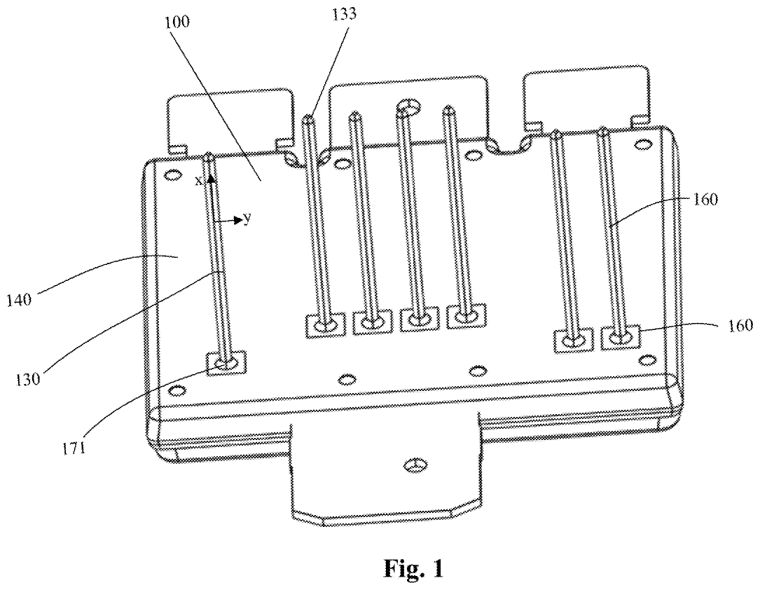

As shown in FIGS. 1-4, the present disclosure provides the package module 100, comprising: the substrate 110, wherein one side surface 115 of the substrate 110 is provided with the metal conductive layer 111; the first terminal 120, wherein the first terminal 120 is a three-dimensional terminal, the first terminal 120 comprises the first surface 121, the second surface 123 and the side surface 122, and the first surface 121 is electrically connected to the metal conductive layer 111; the first encapsulating member 140, encapsulating one side surface 115 of the substrate 110 and the side surface 122 of the first terminal 120, the first encapsulating member 140 is provided with the recess 160 corresponding to the first terminal 120, and the recess 160 is configured to expose the second surface 123; the second terminal 130, wherein the second terminal 130 comprises the first end 131, and the first end 131 is electrically connected to the second surface 123 of the first terminal 120; and the second encapsulating member 150, encapsulating the second surface 123 of the first terminal 120, the first end 131 of the second terminal 130, and at least a portion of the second terminal 130.

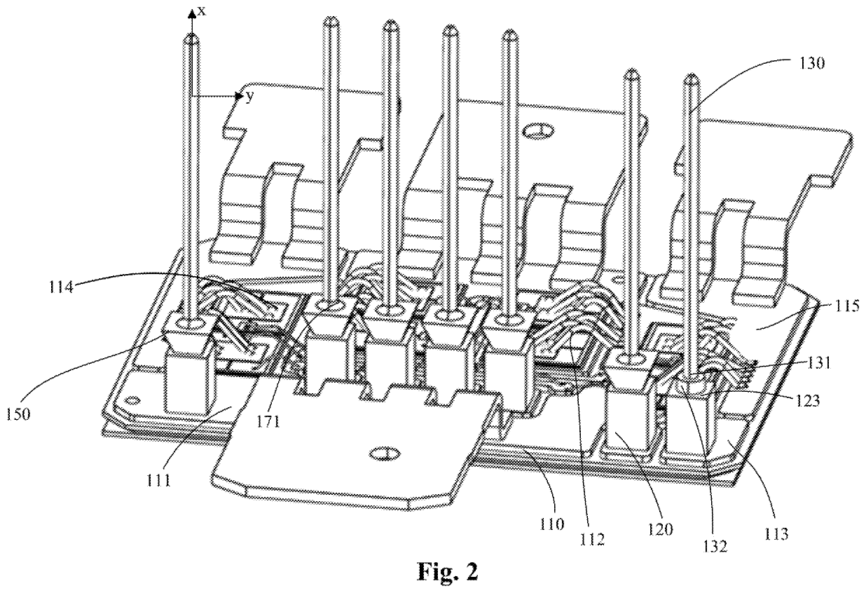

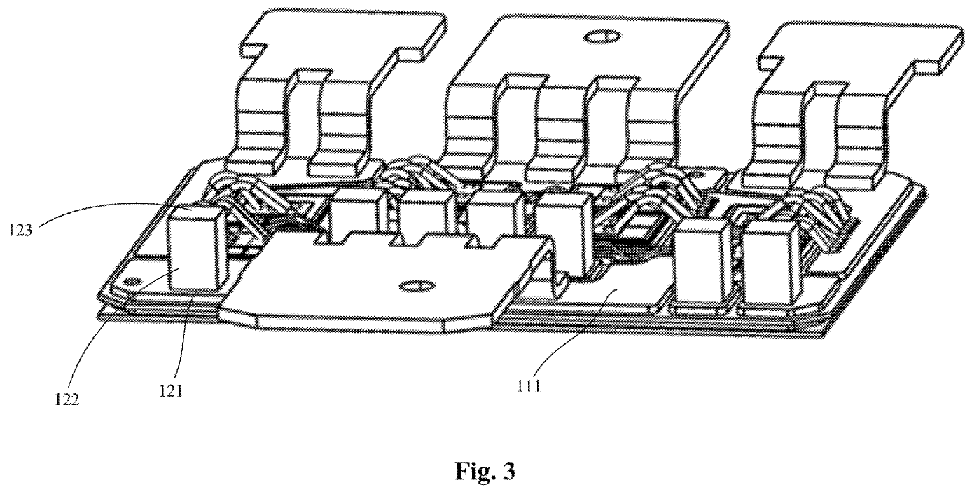

Referring to FIGS. 2-3, the first surface 121 of the first terminal 120 is electrically connected to the metal conductive layer 111 of the substrate 110, and is arranged at a certain height along the first direction x. Referring to FIGS. 1-3, the first end 131 of the second terminal 130 is disposed in the recess 160, and the first end 131 is electrically connected to the second surface 123, so that the second terminal 130 is electrically connected to the metal conductive layer 111 of the substrate 110. As shown in FIG. 1, the second terminal 130 extends along the first direction x and can be electrically connected to an external circuit (not shown), so as to electrically connect the external circuit to the package module 100. As shown in FIG. 2, the first terminal 120 and the second terminal 130 can be arranged at different positions of the metal conductive layer 111, so as to connect the circuits on the metal conductive layer 111 and form a shortest path for circuit connection. The first terminal 120 and the second terminal 130 can be connected to the power circuit of the metal conductive layer 111 to form a power terminal; and can also be connected to the signal circuit of the metal conductive layer 111 to form a signal terminal. By arranging the first terminal 120 and the second terminal 130 along the first direction x, the area of the substrate 110 can be fully utilized, which is beneficial to the pinout of the package module 100; the electrical clearance and creepage distance between packaged pins can be increased; and the impedance and parasitic inductance between the substrate circuit and the second terminal 130 can be reduced.

With continued reference to FIG. 2, the metal conductive layer 111 of the substrate 110 is provided with the substrate circuit 113, i.e., the substrate circuit 113 formed by patterning the metal conductive layer 111. In some embodiments, the package module 100 further comprises the electronic component 114, the electronic component 114 is electrically connected to the metal conductive layer 111, the electronic component 114 may be various chips, power semiconductors, and the like, and the number of the electronic components 114 is greater than or equal to 1. The electronic component 114 can be connected to the metal conductive layer 111 through a lead frame (not shown), or connected to the metal conductive layer 111 through a connecting metal strip (not shown), or connected to the metal conductive layer 111 through the bonding wire 112.

In some embodiments, the substrate 110 may be a DBC (Direct Bonded Copper) ceramic substrate or an AMB (Active Metal Brazing) ceramic substrate. The DBC ceramic substrate is a composite substrate fabricated by hot-melt bonding process, in which copper foil is directly sintered to the surfaces of Al₂O₃ and AlN ceramics at high temperature. The AMB ceramic substrate is developed based on DBC technology. At a high temperature of approximately 800° C., the AgCu solder containing active elements Ti and Zr wets and reacts at the interface between ceramic and metal, thereby achieving heterogeneous bonding between ceramic and metal.

In some embodiments, as shown in FIG. 3, the first terminal 120 is a solid three-dimensional terminal, and the material of the first terminal 120 is a metal or a metal alloy, such as copper or copper alloy. The shape of the first terminal 120 may be a cube, a cuboid, a cylinder or a polygonal prism. Configuring the first terminal 120 as a solid three-dimensional terminal can improve the rigidity of the first terminal 120, and prevent the first terminal 120 from deforming during subsequent processes, which would result in the first terminal 120 being unable to function normally.

In some embodiments, as shown in FIG. 3, the first surface 121 of the first terminal 120 is electrically connected to the metal conductive layer 111, and the electrical connection is realized by sintering, wherein the sintering materials used may be nano-silver paste, nano-silver powder, nano-copper paste, or the like. The sintering processes comprise pressure-assisted sintering and pressureless sintering. For pressure-assisted sintering, it is necessary to apply pressure to the first terminal 120 and the substrate 110, the pressure ranges from 10 MPa to 30 MPa, the sintering temperature ranges from 210° C. to 280° C., and the sintering duration ranges from 5 minutes to 15 minutes. After the pressure-assisted sintering, the bonding strength is relatively high, and the bonding strength at the contact interface between the first surface 121 and the metal conductive layer 111 can reach 60 kgf. For pressureless sintering, it is not necessary to apply pressure to the first terminal 120 and the metal conductive layer 111, and the sintering duration ranges from 2 hours to 4 hours. The bonding strength formed by pressureless sintering is relatively weak, and the bonding strength can reach 20 kgf. If the first terminal 120 and the substrate 110 can withstand the pressure applied by pressure-assisted sintering, the pressure-assisted sintering is preferably adopted to realize the electrical connection between the first terminal 120 and the metal conductive layer 111.

In some embodiments, the manner of electrically connecting the first terminal 120 to the metal conductive layer 111 is brazing, and the brazing comprises soft soldering and hard soldering classified according to the type of solder adopted. Soft soldering refers to a welding method for connecting metal components by using a solder with a melting point lower than 260° C., and the solder is a tin-based alloy, such as solder paste. Due to the lower welding temperature of soft soldering, the adoption of soft soldering can effectively protect the heat-sensitive elements inside the package module. Hard soldering refers to a method for connecting two or more metal components together by using a solder with a melting point higher than 450° C., and the solder may be a silver-based solder or a copper-based solder. The joint formed by hard soldering has relatively high strength, which can provide reliable connection for the first terminal 120 and the metal conductive layer 111.

In some embodiments, the first terminal 120 and the metal conductive layer 111 are electrically connected by means of ultrasonic welding. That is, high-frequency vibration waves are transmitted to the surfaces of two objects to be welded, and under pressure, the surfaces of the two objects rub against each other to form intermolecular fusion. The method of ultrasonic welding does not require solder paste or solder, provides high weld joint strength and low production cost, but high-frequency vibration may cause cracking of the substrate 110.

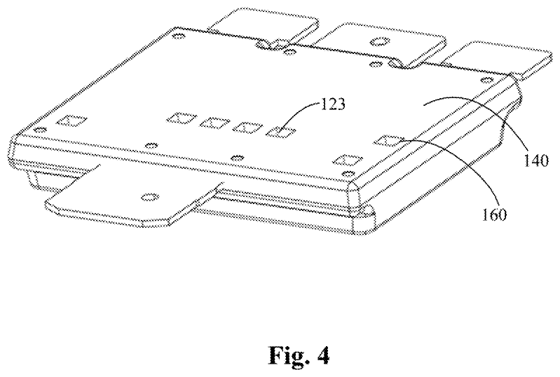

In some embodiments, as shown in FIG. 3, the second surface 123 of the first terminal 120 is opposite to the first surface 121, and the side surface 122 refers to the circumferential surface of the first terminal 120. As shown in FIG. 2, one side surface 115 of the substrate refers to the upper surface of the substrate 110, i.e., the surface electrically connected to the first terminal 120. As shown in FIGS. 2 and 4, the first encapsulating member 140 encapsulates one side surface 115 of the substrate 110, the first surface 121 and the side surface 122 of the first terminal 120. The first encapsulating member 140 is provided with the recess 160 corresponding to the first terminal 120, and the recess 160 is configured to expose the second surface 123.

In some embodiments, a molding mold (not shown) may be used to manufacture the package module 100. The molding mold is configured to mold the substrate 110, the first terminal 120, the electronic component 114, the bonding wire 112, the metal strip, and the like. The molding mold comprises an upper mold and a lower mold, and the lower mold is configured to carry the substrate 110, the first terminal 120, the electronic component 114, the bonding wire 112 and the metal strip. A positioning structure may further be provided in the lower mold, so that the substrate 110 is located at a specific position in the lower mold.

In some embodiments, the upper mold comprises an upper mold body and a moving pin, and the upper mold and the lower mold together form an injection molding cavity. The moving pin may be a metal column connected to the upper mold, which is aligned with the first terminal 120 and is in close contact with the second surface 123. The number and positions of the moving pins correspond one-to-one to the number and positions of the first terminals 120, and they are used to form the recess 160 during molding. The recess 160 corresponds to the first terminal 120, and is used to expose the second surface 123 of the first terminal 120. The upper mold may also include an upper mold body and a pin, wherein the pin is fixed on the upper mold. The number and positions of the pins correspond one-to-one to the number and positions of the first terminals 120, and they are used to form the recess 160.

By arranging the recess 160 above the first terminal 120, overflowed molding compound can be prevented from encapsulating the metal conductive layer 111 corresponding to the recess 160 when molding the first encapsulating member 140. In the absence of the first terminal 120, the molding compound directly covers the metal conductive layer 111 corresponding to the recess 160, thus affecting the subsequent electrical connection of terminals. When the first terminal 120 is provided, the overflowed molding compound will not cover the metal conductive layer 111 corresponding to the recess 160. Even if overflow of molding compound occurs, the overflow of molding compound only remains on the second surface 123. Moreover, the first terminal 120 has a certain height, so the overflow of molding compound on the second surface 123 can be easily removed, which improves the yield rate of the package module 100.

In some embodiments, with reference to FIGS. 2 and 4, the second encapsulating member 150 in FIG. 2 is obtained by completely filling the recess 160, thus, the shape of the recess 160 can be determined from the content shown in FIGS. 2 and 4. The cross-sectional area of the recess 160 along the second direction y gradually increases from the side close to the substrate 110 to the side away from the substrate 110. For example, the recess 160 is in the shape of an inverted frustum, with a smaller cross-sectional area on the side close to the substrate 110 and a larger cross-sectional area on the side away from the substrate 110. This shape arrangement is beneficial to the flow of the molding compound and is not prone to generate bubble voids, thereby improving the quality of the encapsulating member. After the first encapsulating member 140 is formed by molding through a mold, the demolding operation is also easier to perform, which prevents the first encapsulating member 140 from being damaged during the demolding process.

In some embodiments, as shown in FIG. 2, the second terminal 130 comprises the first end 131, the first end 131 is disposed adjacent to the second surface 123 of the first terminal 120 and is electrically connected to the second surface 123. The manners of electrically connecting the first end 131 to the second surface 123 comprise sintering, brazing, laser welding, and the like. Laser welding, also known as laser beam welding, is an advanced welding technology that utilizes a high-energy-density laser beam as a heat source, featuring fast welding speed and high precision. Laser welding can melt the connecting material in a short period of time, and as the laser beam moves, the material cools and solidifies, thereby completing the welding process.

In some embodiments, the first end 131 of the second terminal 130 is a straight end (not shown). In some embodiments, as shown in FIG. 2, the first end 131 of the second terminal 130 is a flange 132. The cross-sectional area of the flange 132 is larger than the cross-sectional area of the first end 131 when the first end 131 is a straight end. The cross-sectional area referred to herein is that of the flange 132 and the first end 131 taken along the second direction y. The purpose of providing the flange 132 is to increase the current carrying capacity of the second terminal 130, and prevent insufficient current conduction capability between the first terminal 120 and the second terminal 130 caused by excessive current. Increasing the contact area between the second terminal 130 and the first terminal 120 also improves the connection stability therebetween.

In some embodiments, the second terminal 130 is made of metal or a metal alloy, such as copper or a copper alloy. The flange 132 of the first end 131 is a solid three-dimensional component, and its shape may be cubic, cuboid, cylindrical, or prismatic with a polygonal cross-section.

In some embodiments, the second terminal 130 may be formed as a single piece, and the flange 132 and the second terminal 130 are integrally die-cast. The second terminal 130 may also be composed of two or more pieces, for example, the flange 132 is provided on the second terminal 130.

In some embodiments, as shown in FIGS. 1-2, the second terminal 130 further comprises the shaft 134 with a rectangular or circular outer periphery, for example, a circular needle-shaped shaft 134. The shaft 134 can extend along the first direction x, and is electrically connected to an external circuit. The manners of electrical connection between the shaft and the outside include physical coupling, sintering, brazing and the like, wherein the physical coupling comprises plug-in connection, fusion welding, etc. In some embodiments, the shaft 134 may be a hollow shaft or a solid shaft.

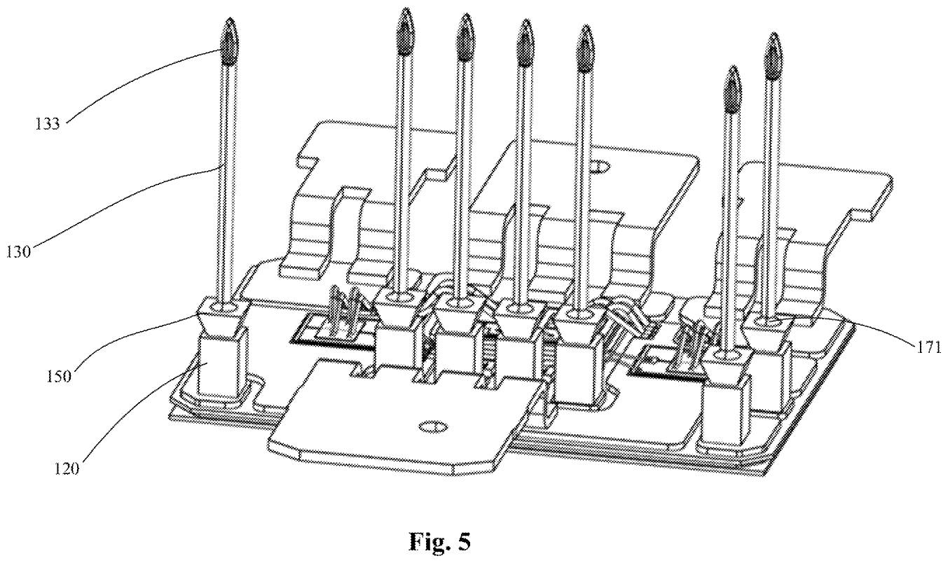

In some embodiments, as shown in FIGS. 1 and 5., the second terminal 130 further comprises the connecting terminal 133, and the connecting terminal 133 is arranged at an end of the second terminal 130 away from the second surface 123. The connecting terminal 133 comprises a pogo pin connector, a sealed annular contact terminal, and a fish-eye contact terminal. The fish-eye terminal consists of a root portion, two elastic portions and an insertion leg portion. The elastic portions are arc-shaped, the two elastic portions are arranged opposite to each other, and form a fish-eye hole. During installation, the elastic portions are squeezed to undergo elastic contraction, so as to perfectly fit with a conductive hole of an external circuit. The connecting terminal 133 can be integrally formed with the second terminal 130, for example, formed by die casting, or can be arranged separately, and the connecting terminal 133 is mounted on the second terminal 130. The connecting terminal enables the second terminal 130 to be connected to an external circuit (not shown) more stably.

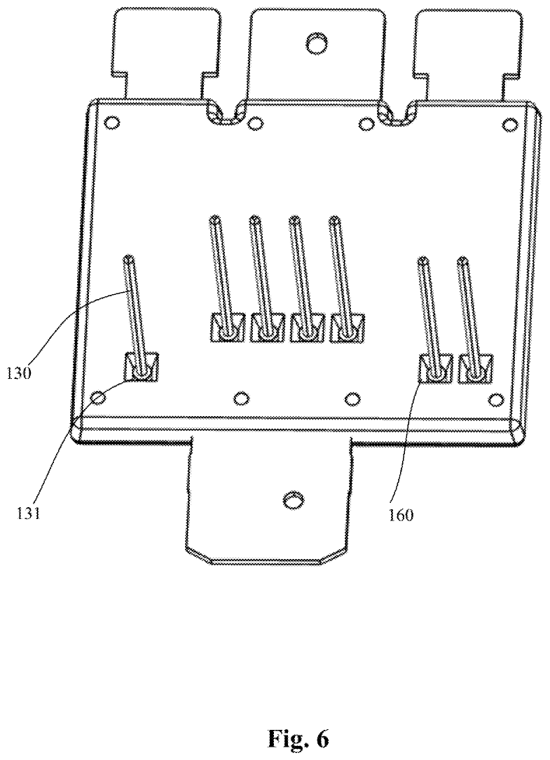

In some embodiments, as shown in FIGS. 1 and 6, the height of the first end 131 (flange 132) is lower than the depth of the recess 160, so that it is disposed in the recess 160 and encapsulated by the second encapsulating member 150 through molding. The depth of the recess 160 should not be too small, and it is appropriate as long as it can accommodate the first end 131 (flange 132). Referring to FIG. 4, the depth of the recess 160 is greater than or equal to 0.5 mm, for example, 0.5 mm, 0.6 mm, 0.7 mm, 0.8 mm and 0.9 mm, etc. The recess 160 is a shallow recess, and its depth refers to the height of the upper surface of the first encapsulating member 140 where the recess 160 is located relative to the second surface 123 of the first terminal 120. The second encapsulating member 150 encapsulates the second surface 123 of the first terminal 120, the first end 131 (flange 132) of the second terminal 130 and at least a portion of the second terminal 130. In these embodiments, disposing the first end 131 (flange 132) in the recess 160, and the second encapsulating member 150 encapsulating the first end 131 (flange 132), the second surface 123 and a portion of the second terminal 130, can provide insulation performance of the encapsulation molding for the first end 131 (flange 132) of the first terminal 120 and the second terminal 130. The second encapsulating member 150 can also prevent the first terminal 120 and the first end 131 (flange 132) from external corrosion and other possible damages, can also prevent bending between the first terminal 120 and the second terminal 130, improve physical strength and improve the reliability of the package module 100.

In some embodiments, as shown in FIGS. 1-2, the second encapsulating member 150 comprises the protrusion 171, the protrusion 171 surrounds a portion of the circumferential surface of the second terminal 130, and the protrusion 171 is conical or dome-shaped. When the second encapsulating member 150 is formed by potting, the molding compound is poured from the opening of the recess 160 and flows toward the bottom of the recess 160, and the molding compound completely fills the entire recess 160. With further reference to FIGS. 1-2, the second encapsulating member 150 comprises a plurality of protrusions 171, the protrusions 171 are located at the top of the second encapsulating member 150, that is, the protrusions 171 are slightly higher than the upper surface of the first encapsulating member 140, such that the portion of the second encapsulating member 150 exposed out of the recess 160 presents a volcanic shape. The protrusion 171 is formed by the cohesive force of the molding compound, surrounds the circumferential surface of the second terminal 130, and is conical or dome-shaped. The protrusion 171 can provide stronger insulation performance of the encapsulation molding and physical strength for the first terminal 120 and the second terminal 130, so that the junction of the first terminal 120 and the second terminal 130 is not easily corroded, and the second terminal 130 is not prone to bending.

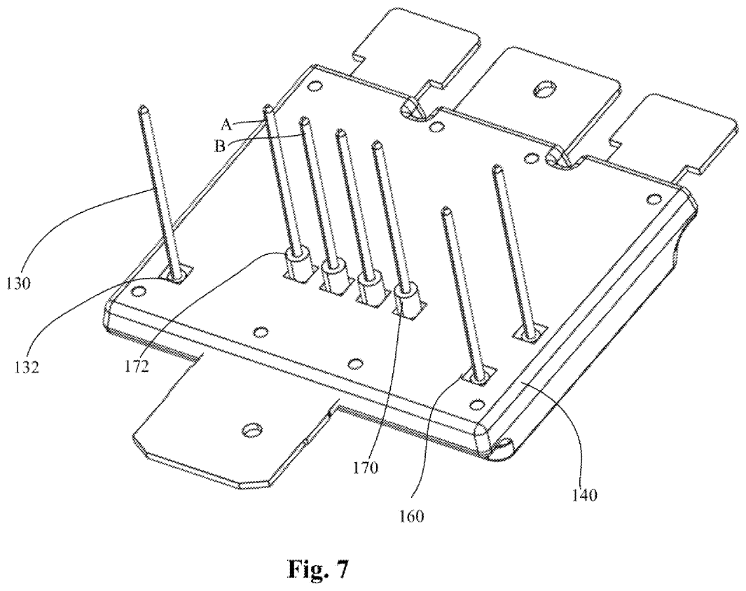

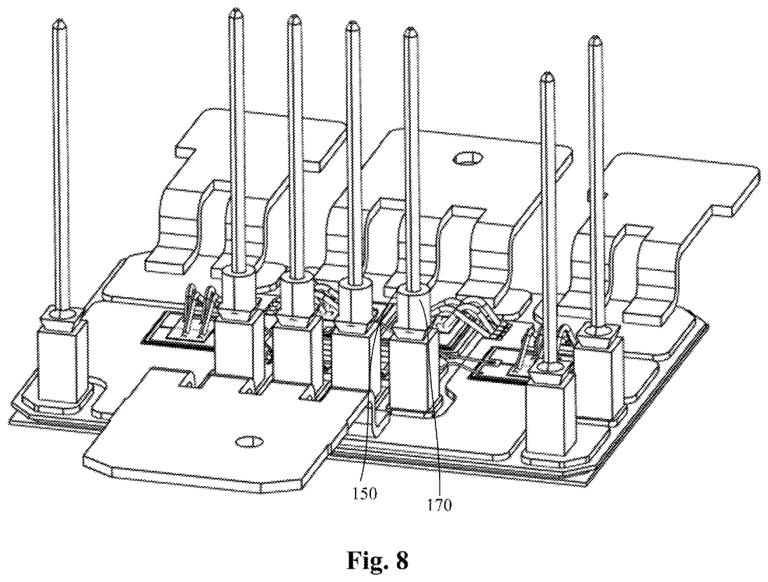

In some embodiments, as shown in FIGS. 7-8, the package module 100 further comprises the sleeve 170, the sleeve 170 is fitted over the second terminal 130, and forms an annular space 172 with the second terminal 130; the bottom of the sleeve 170 extends to the recess 160, and the second encapsulating member 150 extends to completely fill the annular space 172 and encapsulates a portion of the circumferential surface of the second terminal 130. The sleeve 170 is made of an insulating material, and is configured to be hollow, the inner diameter of the hollow part of the sleeve is larger than the width or diameter of the second terminal 130, so that it can be sleeved on the second terminal 130. The purpose of arranging the sleeve 170 is to enable the second encapsulating member 150 to encapsulate the circumferential surface of the second terminal 130 along the annular space 172, so as to provide a larger creepage distance and meet the creepage distance requirement for high voltage applications. Creepage distance refers to the shortest path length along the surface of the insulating material between two conductive components, and its core function is to ensure that no leakage current or dielectric breakdown occurs along the surface of the insulator under humid, polluted or high voltage conditions. In these embodiments, the creepage distance refers to the creepage distance between a plurality of second terminals 130, to ensure that no leakage current or dielectric breakdown occurs between the second terminals 130.

In some embodiments, the lengths of the sleeve 170 and the second encapsulating member 150 can be adapted according to design requirements for creepage distance. Referring to FIG. 7, when the second terminal A and the second terminal B are not provided with sleeves, the original creepage distance is the connecting line between the second terminal A and the second terminal B along the surface of the encapsulating member, and assuming that the original creepage distance is 3 mm. Under certain conditions, in order to enhance the insulation performance between the first terminal A and the second terminal B, the creepage distance needs to be set to 6 mm. In this case, the sleeve 170 with the length of 4 mm may be arranged on the second terminal A, the bottom (1 mm) of the sleeve 170 extends into the recess 160, and potting is performed in the annular space 172 between the sleeve 170 and the second terminal A. The creepage distance can be increased by 3 mm after potting. At this time, the creepage distance between the second terminal A and the second terminal B is 6 mm, and the creepage distance comprises the length (3 mm) of the sleeve 170 that is higher than the upper surface of the first encapsulating member 140 and the length of the original creepage distance (3 mm). After increasing the creepage distance, the insulation performance between a plurality of second terminals 130 can be more reliably ensured, so that the package module 100 has higher reliability.

In these embodiments, as shown in FIGS. 7-8, the depth of the recess 160 is greater than or equal to 1 mm, such as 1 mm, 1.1 mm, 1.2 mm, 1.3 mm, 1.4 mm, 1.5 mm, 1.6 mm, 1.7 mm and 1.8 mm, etc. The bottom of the sleeve 170 needs to extend to the recess 160, so as to better fix the sleeve 170 and facilitate the subsequent formation of the second encapsulating member 150. If the recess 160 is too shallow, the sleeve 170 cannot be stably arranged on the second terminal 130, which affects the subsequent encapsulation and potting.

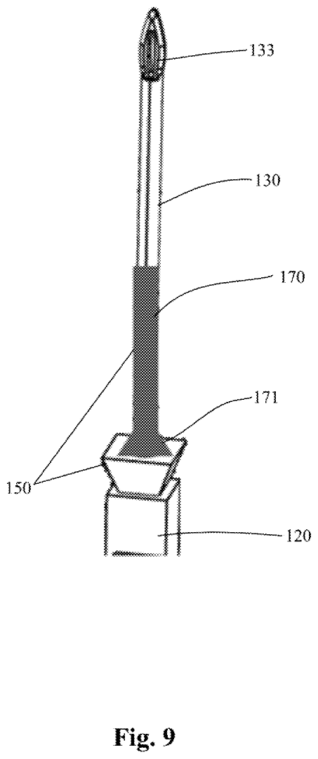

In some embodiments, as shown in FIGS. 7 and 9, the second encapsulating member 150 comprises the protrusion 171, wherein the protrusion 171 is disposed at the junction between the bottom of the sleeve 170 and the first encapsulating member 140, and the protrusion 171 is conical or dome-shaped. When potting to form the second encapsulating member 150, the molding compound is poured from the opening at the top of the sleeve 170 and flows toward the bottom of the sleeve 170, and the molding compound will completely fill the entire annular space 172 and the recess 160. With further reference to FIGS. 7 and 9, the second encapsulating member 150 comprises a plurality of protrusions 171, and the protrusions 171 are disposed at the junction between the bottom of the sleeve 170 and the first encapsulating member 140, such that the bottom of the sleeve 170 after molding presents a volcanic shape. The protrusion 171 is formed due to the cohesive force of the molding compound, and the protrusion 171 is conical or dome-shaped. The protrusion 171 can provide stronger insulation performance of the encapsulation molding and physical strength for the first end 131 of the second terminal 130, so that the first end 131 is not prone to corrosion and bending.

In some embodiments, as shown in FIGS. 1 and 7, the package module 100 includes a plurality of first terminals 120, a plurality of recesses 160, a plurality of second encapsulating members 150, a plurality of sleeves 170 and a plurality of second terminals 130.

In the package module 100 of the present disclosure, the first encapsulating member 140 encapsulates one side surface 115 of the substrate 110 and the side surface 122 of the first terminal 120, the second encapsulating member 150 encapsulates the second surface 123 of the first terminal 120, the first end 131 of the second terminal 130, and at least a portion of the second terminal 130, such arrangement can effectively protect the first terminal 120 and the second terminal 130, prevent the first terminal 120 and the second terminal 130 from external corrosion, and improve reliability. The second encapsulating member can also increase the electrical clearance and creepage distance between the terminals of the package module.

Therefore, the package module 100 of the present disclosure increases the electrical clearance and creepage distance between terminals of the package module 100. Terminals with electrical properties can be extended from the upper surface of the package module 100, and the electrical clearance and creepage distance between the terminals of the package module 100 can be further increased via the second encapsulating member 150, thereby achieving protection capability as the package module without upper surface connection terminals, and improve the reliability of the package module 100.

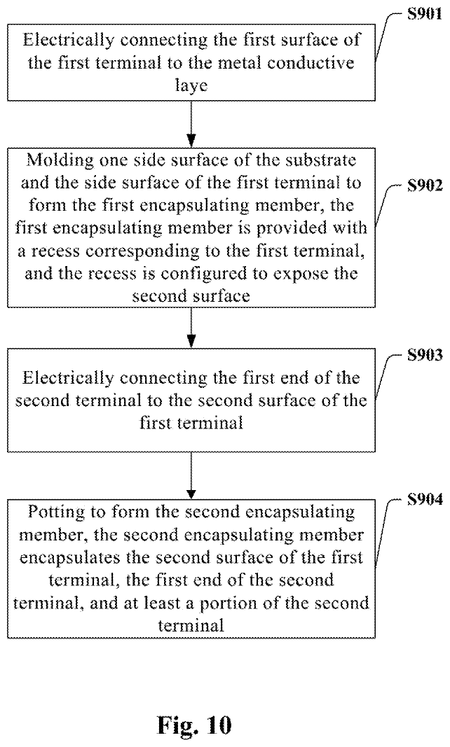

The present disclosure also provides a method of manufacturing the package module 100, which is configured to manufacture the package module as described above. As shown in FIG. 10, the method of manufacturing the package module comprises:
S901, electrically connecting the first surface 121 of the first terminal 120 to the metal conductive layer 111;
S902, molding one side surface of the substrate 110 and the side surface 122 of the first terminal 120 to form the first encapsulating member 140, the first encapsulating member 140 is provided with a recess 160 corresponding to the first terminal 120, and the recess 160 is configured to expose the second surface 123;
S903, electrically connecting the first end 131 of the second terminal 130 to the second surface 123 of the first terminal 120;
S904, potting to form the second encapsulating member 150, the second encapsulating member 150 encapsulates the second surface 123 of the first terminal 120, the first end 131 of the second terminal 130, and at least a portion of the second terminal 130.

The method of manufacturing the package module is implemented by using the components of the encapsulating module 100 as described above. Therefore, all the descriptions of the package module 100 in the foregoing content can be applied to the description of the manufacturing method of the present disclosure, and the structure, shape, connection mode and other aspects of the components of the encapsulating module 100 will not be elaborated herein.

In step S901, referring to FIGS. 2 and 3, the first surface 121 of the first terminal 120 is electrically connected to the metal conductive layer 111. Electronic components are further arranged on the substrate 110, and the electronic components are electrically connected to the metal conductive layer 111 of the substrate 110 through lead frames, bonding wires and metal strips. External terminals are further arranged on the substrate 110, and the external terminals are arranged around the substrate 110 and extend along the second direction y.

In step S902, referring to FIG. 2, one side surface 115 of the substrate 110 refers to the one side surface 115 electrically connected to the first surface 121 of the first terminal 120. The molding compounds adopted for molding are epoxy resin, silicone resin, polyurethane resin and the like.

In step S903, referring to FIGS. 1, 2 and 5, the second terminal 130 comprises the first end 131, and the first end 131 is a flange 132. The flange 132 is disposed in the recess 160 and is electrically connected to the second surface 123. The surface area of the flange 132 is approximately equal to the surface area of the second surface 123, which provides a large contact area for connection between the first terminal 120 and the second terminal 130. The second terminal 130 further comprises the shaft 134 with a rectangular or circular outer periphery and the connecting terminal 133.

In step S904, referring to FIGS. 1 and 6, potting into the recess 160 to form the second encapsulating member 150. The second encapsulating member 150 encapsulates the second surface 123, the first end 131 and a portion of the second terminal 130. The molding compounds adopted for potting are epoxy resin, silicone resin, polyurethane resin and the like.

In some embodiments, the method further comprises: S905, fitting the sleeve 170 over the second terminal 130 to form the annular space 172 between the sleeve 170 and the second terminal 130, and extending the bottom of the sleeve 170 to the recess 160, wherein the second encapsulating member 150 further completely fills the annular space 172 and encapsulates the circumferential surface of the second terminal 130.

As shown in FIGS. 7 and 8, the sleeve 170 is a cylindrical sleeve 170, wherein the sleeve 170 is fitted over the second terminal 130 and forms the annular space 172 with the second terminal; the bottom of the sleeve 170 extends to the recess 160, the second encapsulating member 150 completely fills the annular space 172 and encapsulates a portion of the circumferential surface of the second terminal 130. It is not necessary to provide the sleeve 170 for all second terminals 130, and the sleeve 170 is arranged according to the actual creepage distance requirement of the second terminal 130.

The present disclosure uses specific words to describe the embodiments of the present disclosure. Words such as “one embodiment”, “an embodiment”, and/or “some embodiments” mean a certain feature, structure, or characteristic related to at least one embodiment of the present disclosure. Therefore, it should be emphasized and noted that references to “an embodiment” or “one embodiment” or “an alternative embodiment” in different places in this specification do not necessarily refer to the same embodiment. In addition, certain features, structures, or characteristics in one or more embodiments of the present disclosure may be appropriately combined.

Similarly, it should be noted that, in order to simplify the expression of the disclosure of the present disclosure and facilitate the understanding of one or more inventive embodiments, in the foregoing description of the embodiments of the present disclosure, multiple features are sometimes grouped into one embodiment, one drawing, or the description thereof. However, this disclosure method does not mean that the subject matter of the present disclosure requires more features than those mentioned. In fact, an embodiment comprises fewer features than all features of the single embodiment disclosed above.

In some embodiments, numbers describing components and attribute quantities are used. It should be understood that such numbers used to describe the embodiments are modified by the modifier “about”, “approximately”, or “substantially” in some examples. Unless otherwise stated, “about”, “approximately”, or “substantially” indicates that the number allows a variation of ±20%. Correspondingly, in some embodiments, the numerical parameters used in the specification and claims are approximate values, and the approximate values can be changed according to the characteristics required by individual embodiments. In some embodiments, the numerical parameters should take into account the specified significant digits and adopt the method of retaining general digits. Although the numerical ranges and parameters used to confirm the breadth of the scope in some embodiments of the present disclosure are approximate values, in specific embodiments, such numerical settings are as precise as possible within the feasible range.

1. A package module, comprising:
a substrate, wherein one side surface of the substrate is provided with a metal conductive layer;
a first terminal, wherein the first terminal is a three-dimensional terminal, the first terminal comprises a first surface, a second surface and a side surface, and the first surface is electrically connected to the metal conductive layer;
a first encapsulating member, encapsulating one side surface of the substrate and the side surface of the first terminal, the first encapsulating member is provided with a recess corresponding to the first terminal, and the recess is configured to expose the second surface;
a second terminal, wherein the second terminal comprising a first end, and the first end being electrically connected to the second surface of the first terminal; and
a second encapsulating member, encapsulating the second surface of the first terminal, the first end of the second terminal, and at least a portion of the second terminal.

2. The package module according to claim 1, wherein a depth of the recess is greater than or equal to 0.5 millimeters.

3. The package module according to claim 1, further comprising: a sleeve, wherein the sleeve is fitted over the second terminal and forms an annular space with the second terminal;
a bottom of the sleeve extends to the recess, the second encapsulating member completely fills the annular space and encapsulates a portion of a circumferential surface of the second terminal.

4. The package module according to claim 3, wherein a depth of the recess is greater than or equal to 1 millimeter.

5. The package module according to claim 1, wherein the first end of the second terminal is a flange.

6. The package module according to claim 1, wherein the second encapsulating member comprises a protrusion, the protrusion surrounds a circumferential surface of the second terminal, and the protrusion is conical or dome-shaped.

7. The package module according to claim 1, wherein a manner of electrically connecting the first surface to the metal conductive layer comprises any one or a combination of more of sintering, brazing and ultrasonic welding.

8. The package module according to claim 1, wherein a manner of electrically connecting the first end to the second surface of the first terminal comprises any one or a combination of more of sintering, brazing and laser welding.

9. A method of manufacturing a package module, wherein the method is configured to manufacture the package module according to claim 1, and the method comprises:
electrically connecting the first surface of the first terminal to the metal conductive layer;
molding one side surface of the substrate and the side surface of the first terminal to form the first encapsulating member, the first encapsulating member is provided with a recess corresponding to the first terminal, and the recess is configured to expose the second surface;
electrically connecting the first end of the second terminal to the second surface of the first terminal; and
potting to form the second encapsulating member, the second encapsulating member encapsulates the second surface of the first terminal, the first end of the second terminal, and at least a portion of the second terminal.

10. The method according to claim 9, further comprising:
fitting a sleeve over the second terminal to form an annular space between the sleeve and the second terminal, and extending a bottom of the sleeve to the recess, wherein the second encapsulating member further completely fills the annular space and encapsulates a portion of a circumferential surface of the second terminal.
